(19) United States
(12) Patent Application Publication
(10) Pub. No.: US 2024/0098929 A1
(43) Pub. Date: Mar. 21, 2024

(54) SERVER CABINET

(71) Applicant: INSPUR SUZHOU INTELLIGENT TECHNOLOGY CO., LTD., Suzhou, Jiangsu (CN)

(72) Inventor: Qianqian WU, Suzhou, Jiangsu (CN)

(73) Assignee: INSPUR SUZHOU INTELLIGENT TECHNOLOGY CO., LTD., Suzhou, Jiangsu (CN)

(21) Appl. No.: 18/263,672

(22) PCT Filed: Nov. 30, 2021
(86) PCT No.: PCT/CN2021/134333

§ 371 Date: Jul. 31, 2023

(30) Foreign Application Priority Data
Jul. 23, 2021 (CN) 202110837885.0

(51) Int. Cl. H05K 7/14

(52) U.S. Cl. CPC H05K 7/1489; H05K 7/1492

(57) ABSTRACT

The disclosure provides a server cabinet, including: a cabinet frame, first mounting flanges detachably and vertically arranged at two sides of a front end of the cabinet frame, second mounting flanges detachably and vertically arranged at the two sides of the front end of the cabinet frame, first support brackets detachably arranged at the two side walls of the cabinet frame and configured for installing an ODCC server, and second support brackets detachably arranged at the two side walls of the cabinet frame and configured for installing an OCP server; wherein a plurality of first mounting holes configured for being matched with a front end of the ODCC server are formed in the first mounting flanges along a height direction, and a plurality of second mounting holes configured for being matched with a front end of the OCP server are formed in the second mounting flanges along the height direction.

### CROSS-REFERENCE TO RELATED APPLICATION

The disclosure is a National Stage Filing of the PCT International Application No. PCT/CN2021/134333 filed on Nov. 30, 2021, which claims priority to Chinese Patent Application No. 202110837885.0, filed to the China National Intellectual Property Administration on Jul. 23, 2021 and entitled “Server Cabinet”, which is incorporated herein by reference in its entirety.

### TECHNICAL FIELD

The disclosure relates to the technical field of servers, and in particular, to a server cabinet.

### BACKGROUND

With the development of electronic technology in China, more and more electronic devices have been widely used.

A server is an important constituent part in an electronic device, and is a device that provides a computing service. Since the server needs to respond to a service request and perform processing, the server has the ability to undertake a service and guarantee the service. According to different service types provided by servers, the servers are classified into a file server, a database server, an application server, a WEB server, and the like. The main composition of the server comprises a processor, a hard disk, a memory, a system bus, etc., which is similar to a general computer architecture, but has high requirements in terms of processing capability, stability, reliability, security, extensibility, manageability, etc.

In the era of big data, a large number of IT devices are placed in cabinets of data centers in a centralized manner. These data centers contain various types of servers, storages, switches, and a large number of cabinets and other infrastructure. Each type of IT devices are composed of various hardware boards, such as a computing module, a storage module, a chassis, and a fan module, etc. A whole cabinet server is an integrally-mounted comprehensive product comprising components such as a cabinet, a server node, a power supply device, a signal interaction device (e.g. a switch), and connecting cables.

Currently, server technology requirements in the Internet industry have been upgraded from industry customization to industry standardization, and are mainly represented by ODCC (Open Data Center Committee) standard in China and OCP (Open Compute Project) standard in the United States. The ODCC standard and the OCP standard are two different standards of whole cabinet servers. A server node conforming to the ODCC standard has a long shape, while a server node conforming to the OCP standard has a short shape, thereby rendering that an ODCC server and an OCP server may not be interchangeably mounted in respective corresponding whole cabinets.

The server cabinet in the related art is either designed for ODCC servers or designed for OCP servers, and thus may not be universally used. When a user has server configuration requirements of both the two standard specifications, two sets of whole cabinets of different specifications are manufactured at the same time, thereby increasing the costs.

Therefore, how to achieve a universal design of a whole machine cabinet, i.e. being compatible with an ODCC standard server and an OCP standard server, thereby reducing configuration costs, is a technical problem faced by a person skilled in the art.

### SUMMARY

Some embodiments of the disclosure is to provide a server cabinet, which may realize a universal design of a whole cabinet, i.e. being compatible with an ODCC standard server and an OCP standard server, thereby reducing configuration costs.

In order to solve the technical problem, some embodiments of the disclosure provide a server cabinet, including: a cabinet frame, first mounting flanges detachably and vertically arranged at two sides of a front end of the cabinet frame, second mounting flanges detachably and vertically arranged at the two sides of the front end of the cabinet frame, first support brackets detachably arranged at the two side walls of the cabinet frame and configured for installing an ODCC server, and second support brackets detachably arranged at the two side walls of the cabinet frame and configured for installing an OCP server, wherein a plurality of first mounting holes configured for being matched with a front end of the ODCC server are formed in the first mounting flanges along a height direction, and a plurality of second mounting holes configured for being matched with a front end of the OCP server are formed in the second mounting flanges along the height direction.

In an embodiment mode, front vertical posts are provided at the two sides of the front end of the cabinet frame, and the first mounting flanges and the second mounting flanges are both provided on the front vertical posts.

In an embodiment mode, a plurality of columns of mounting holes are provided on surfaces of the front vertical posts along a mounting direction, and the first mounting flanges and the second mounting flanges respectively match corresponding columns of mounting holes of the plurality of columns of mounting holes.

In an embodiment mode, the first mounting flanges and the second mounting flanges are integrally connected by connecting plates, and the connecting plates are detachably provided on the front vertical posts.

In an embodiment mode, the first mounting flanges are closer to the front end of the cabinet frame than the second mounting flanges.

In an embodiment mode, both the first mounting holes and the second mounting holes are square holes, round holes, or polygonal holes.

In an embodiment mode, both the first support brackets and the second support brackets are U-shaped supports, and each inner width of the first support brackets is equivalent to a height of the ODCC server, and each inner width of the second support brackets is equivalent to a height of the OCP server.

In an embodiment mode, rear ends of the first support brackets and the second support brackets are respectively provided with limiting blocks for blocking the ODCC server and the OCP server to limit the maximum installing depth of the ODCC server and the OCP server in the cabinet frame.

In an embodiment mode, the server cabinet further includes first locking attachment members provided on side walls of a rear end of the cabinet frame and for fixing ODCC busbars, and second locking attachment members provided on side walls of the rear end of the cabinet frame and for fixing OCP busbars.

In an embodiment mode, the server cabinet further includes a butt block provided at a middle part in the height direction of the side walls of the rear end of the cabinet frame and for vertically abutting joint two of the ODCC busbars; and a butt cross beam transversely connected between the two side walls of the rear end of the cabinet frame and for vertically abutting joint two of the OCP busbars.

The server cabinet provided in some embodiments of the disclosure mainly includes the cabinet frame, first mounting flanges, second mounting flanges, first support brackets and second support brackets. The cabinet frame is a main structure of the server cabinet, and is mainly configured to mount server nodes of two specifications, and other parts. The first mounting flanges are vertically arranged at positions on two sides of the front end of the cabinet frame, and are detachably connected to the cabinet frame, so that an assembly/disassembly operation is conveniently performed. The second mounting flanges are also vertically arranged at positions on two sides of the front end of the cabinet frame, and are detachably connected to the cabinet frame, so that an assembly/disassembly operation is conveniently performed. The first support brackets are arranged at the two side walls of the cabinet frame, and are detachably connected to the cabinet frame, so that an assembly/disassembly operation is conveniently performed. The first support brackets are mainly configured for mounting ODCC server, and generally, a plurality of first support brackets are provided at the same time, and are stacked in the height direction of the cabinet frame. The second support brackets are also arranged at the two side walls of the cabinet frame, and are detachably connected to the cabinet frame, so that an assembly/disassembly operation is conveniently performed. The second support brackets are mainly configured for mounting OCP servers, and generally, a plurality of second support brackets are provided at the same time, and are stacked in the height direction of the cabinet frame. Moreover, the plurality of first mounting holes are formed in the first mounting flanges along the height direction, and the first mounting holes are mainly configured to match the front end of the ODCC servers mounted in the first support brackets, so as to lock the ODCC servers in the first support brackets and the cabinet frame.

By the same reasoning, the plurality of second mounting holes are formed in the second mounting flanges along the height direction, and the second mounting holes are mainly configured to match the front ends of the OCP servers mounted in the second support brackets, so as to lock the OCP servers in the second support brackets and the cabinet frame. In this way, in the server cabinet provided in some embodiments of the disclosure, the first support brackets and the second support brackets are provided in the cabinet frame at the same time, ODCC servers and OCP servers are separately installed, and then in combination with the first mounting flanges and the second mounting flanges at the front end of the cabinet frame, the ODCC servers and the OCP servers are separately locked, thereby realizing the universal design of the whole cabinet, i.e. being compatible with ODCC standard servers and OCP standard servers, thereby reducing configuration costs.

### BRIEF DESCRIPTION OF THE DRAWINGS

In order to describe the technical solutions in the embodiments of the disclosure or in the related art more clearly, hereinafter, accompanying drawings requiring to be configured for describing the embodiments or the related art are introduced briefly. Apparently, the accompanying drawings in the following description merely relate to embodiments of the disclosure, and for a person of ordinary skill in the art, other accompanying drawings may also be obtained according to the provided accompanying drawings without involving any inventive effort.

FIG. 1 is a schematic diagram of the whole structure in a specific embodiment provided in the disclosure.

FIG. 2 is an enlarged view of a partial structure of FIG. 1.

FIG. 3 is schematic diagram of a split structure of a first mounting flange and a second mounting flange.

FIG. 4 is schematic diagram of an integrated structure of a first mounting flange and a second mounting flange.

FIG. 5 is a schematic diagram of the specific structure of a first support bracket.

FIG. 6 is a schematic diagram of the specific structure of a second support bracket.

FIG. 7 is a schematic diagram of a matching structure between an ODCC server and first mounting flanges.

FIG. 8 is a schematic diagram of a matching structure between an OCP server and second mounting flanges.

FIG. 9 is a schematic diagram of a matching structure between ODCC busbars and first locking attachment members.

FIG. 10 is a schematic diagram of a partial structure of FIG. 9.

FIG. 11 is a schematic diagram of a matching structure between OCP busbars and second locking attachment members.

FIG. 12 is a schematic diagram of a partial structure of FIG. 11.

In FIGS. 1-12:
ODCC server—a, OCP server—b, ODCC busbar—c, OCP busbar—d,
cabinet frame—1, first mounting flange—2, second mounting flange—3, first support bracket—4, second support bracket—5, connecting plate—6, limiting block—7, first locking attachment member—8, second locking attachment member—9, butt block—10, butt cross beam—11;
front vertical post—101, rear vertical post—102, first mounting hole—21, second mounting hole—31.

### DETAILED DESCRIPTION OF THE EMBODIMENTS

Hereinafter, the technical solutions in embodiments of the disclosure will be described clearly and thoroughly with reference to the accompanying drawings of the embodiments of the disclosure. Obviously, the embodiments as described are some of the embodiments of the disclosure, and are not all of the embodiments of the disclosure. All other embodiments obtained by a person of ordinary skill in the art based on the embodiments of the disclosure without any inventive effort shall all fall within the scope of protection of the disclosure.

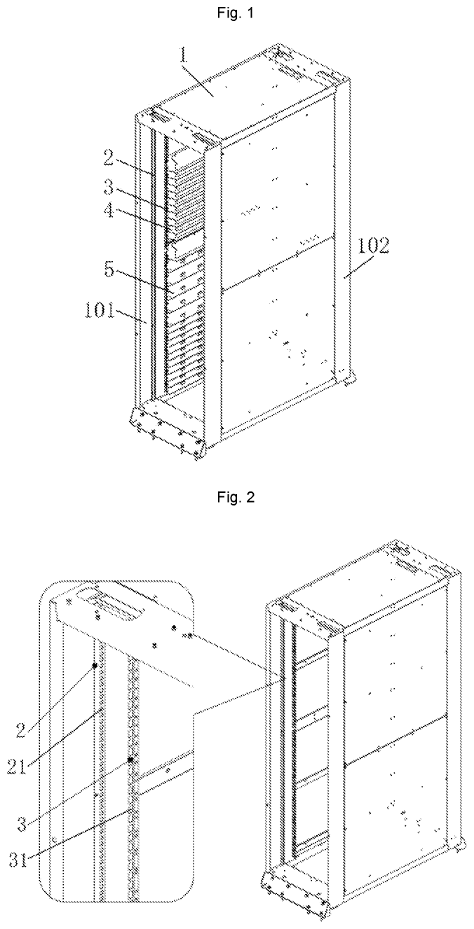

Please refer to FIGS. 1 and 2, FIG. 1 is a schematic diagram of the whole structure in a specific embodiment provided in the disclosure, and FIG. 2 is an enlarged view of a partial structure of FIG. 1.

In a specific embodiment provided in the disclosure, a server cabinet mainly includes a cabinet frame 1, first mounting flanges 2, second mounting flanges 3, first support brackets 4 and second support brackets 5.

The cabinet frame 1 is a main structure of the server cabinet, and is mainly configured to mount server nodes of two specifications, and other parts. Usually, the cabinet frame 1 is generally in the shape of a vertical cuboid, and mainly includes a bottom plate, a top plate, side covers, a front cover, and a rear cover, etc.

The first mounting flanges 2 are vertically arranged at positions on two sides of the front end of the cabinet frame 1, and are detachably connected to the cabinet frame 1, so that an assembly/disassembly operation is conveniently performed.

The second mounting flanges 3 are also vertically arranged at positions on two sides of the front end of the cabinet frame 1, and are detachably connected to the cabinet frame 1, so that an assembly/disassembly operation is conveniently performed.

The first support brackets 4 are arranged at the two side walls of the cabinet frame 1, and are detachably connected to the cabinet frame 1, so that an assembly/disassembly operation is conveniently performed. The first support brackets are mainly configured for mounting ODCC servers a, and generally, a plurality of first support brackets 4 are provided at the same time, and are stacked in the height direction of the cabinet frame 1.

The second support brackets 5 are also arranged at the two side walls of the cabinet frame 1, and are detachably connected to the cabinet frame 1, so that an assembly/disassembly operation is conveniently performed. The second support brackets are mainly configured for mounting OCP server b, and generally, a plurality of second support brackets are provided at the same time, and are stacked in the height direction of the cabinet frame 1.

Moreover, a plurality of first mounting holes 21 are formed in the first mounting flanges 2 along the height direction, and the first mounting holes 21 are mainly configured to match the front ends of the ODCC servers a mounted in the first support brackets 4, so as to lock the ODCC servers a in the first support brackets 4 and the cabinet frame 1.

By the same reasoning, a plurality of second mounting holes 31 are formed in the second mounting flanges 3 along the height direction, and the second mounting holes 31 are mainly configured to match the front ends of the OCP servers b mounted in the second support brackets 5, so as to lock the OCP servers b in the second support brackets 5 and the cabinet frame 1.

In this way, in the server cabinet provided in some embodiments of the disclosure, the first support brackets 4 and the second support brackets 5 are provided in the cabinet frame 1 at the same time, ODCC servers a and OCP servers b are separately installed, and then in combination with the first mounting flanges 2 and the second mounting flanges 3 at the front end of the cabinet frame 1, the ODCC servers a and the OCP servers b are separately locked, thereby realizing the universal design of the whole cabinet, i.e. being compatible with ODCC-standard servers and OCP-standard servers, thereby reducing configuration costs.

In addition, the first mounting flanges 2, the second mounting flanges 3, the first support brackets 4 and the second support brackets 5 are all detachably connected to the cabinet frame 1, so that a user may flexibly adjust the specific mounting positions and/or the number of the four on the cabinet frame 1 according to configuration requirements thereof. For example, the mounting positions of the first mounting flanges 2 and the second mounting flanges 3 on the cabinet frame 1 are exchanged, the mounting number of the first support brackets 4 and the second support brackets 5 on the cabinet frame 1 may be increased or decreased according to requirements, and the mounting positions of the first support brackets 4 and the second support brackets 5 on the cabinet frame 1 may be adjusted according to requirements.

In order to facilitate the assembly and disassembly of the first mounting flanges 2 and the second mounting flanges 3 on the cabinet frame 1, in this embodiment, front vertical posts 101 are vertically arranged on both sides of the front end of the cabinet frame 1, and the first mounting flanges 2 and the second mounting flanges 3 are both arranged on the front vertical posts 101. Generally, the front vertical posts 101 at the two sides are connected to form a rectangular enclosure frame, and are sleeved on the front end of the cabinet frame 1. Correspondingly, the rear end of the cabinet frame 1 may also be provided with a rectangular enclosure frame, in which rear vertical posts 102 on two sides of the cabinet frame are provided, and are mainly configured for mounting ODCC busbars c and OCP busbars d.

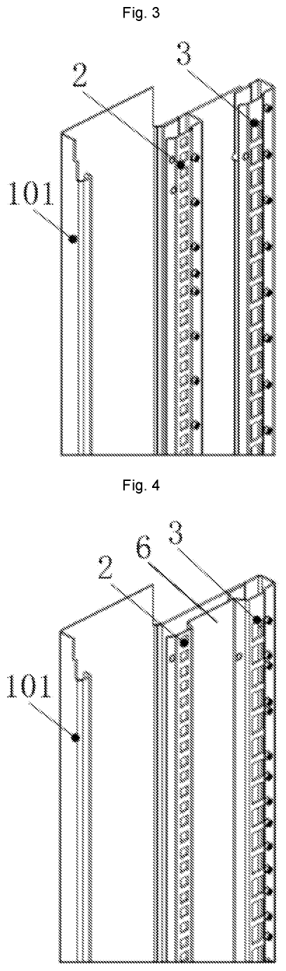

As shown in FIG. 3, FIG. 3 is schematic diagram of a split structure of a first mounting flange 2 and a second mounting flange 3.

In an embodiment regarding the first mounting flanges 2 and the second mounting flanges 3, in order to facilitate independent assembly and disassembly of the first mounting flanges 2 and the second mounting flanges 3, in this embodiment, a plurality of columns of mounting holes, e.g. two columns, are provided on surfaces of the front vertical posts 101 along a mounting direction (depth direction); in addition, the first mounting flanges 2 and the second mounting flanges 3 are separately installed in corresponding columns of mounting holes of the plurality of columns of mounting holes. Such as, each first mounting flange 2 may be mounted in one column of mounting holes by using fasteners such as bolts, and each second mounting flange 3 may be mounted in another column of mounting holes by using fasteners such as bolts. When the mounting positions need to be adjusted, it is necessary to detach the first mounting flange 2 or the second mounting flange 3 from the front vertical post 101 and then form connection with another column of mounting holes again.

As shown in FIG. 4, FIG. 4 is schematic diagram of an integrated structure of a first mounting flange 2 and a second mounting flange 3.

In another embodiment regarding the first mounting flanges 2 and the second mounting flanges 3, in order to improve the integration level, the first mounting flanges 2 and the second mounting flanges 3 are integrally connected by connecting plates 6, and at the same time, the connecting plates 6 are then connected to the front vertical posts 101. Such as, the connecting plates 6 may also be connected to the front vertical posts 101 by fasteners such as bolts, so that the first mounting flanges 2 and the second mounting flanges 3 are assembled and disassembled while the connecting plates 6 are assembled and disassembled.

In addition, considering that the ODCC server a has a longer length and the OCP server b has a shorter length, in this embodiment, the first mounting flanges 2 are closer to the front end of the cabinet frame 1 than the second mounting flanges 3. Such as, the first mounting flanges 2 stand on the outer end edge positions of the front vertical posts 101, and the second mounting flanges 3 stand on the inner end edge positions of the front vertical posts 101, that is, each second mounting flange 3 has a larger installing depth. In this way, on the basis that rear ends of the ODCC servers a and the OCP servers b are flush, the front ends thereof respectively match the first mounting flanges 2 and the second mounting flanges 3.

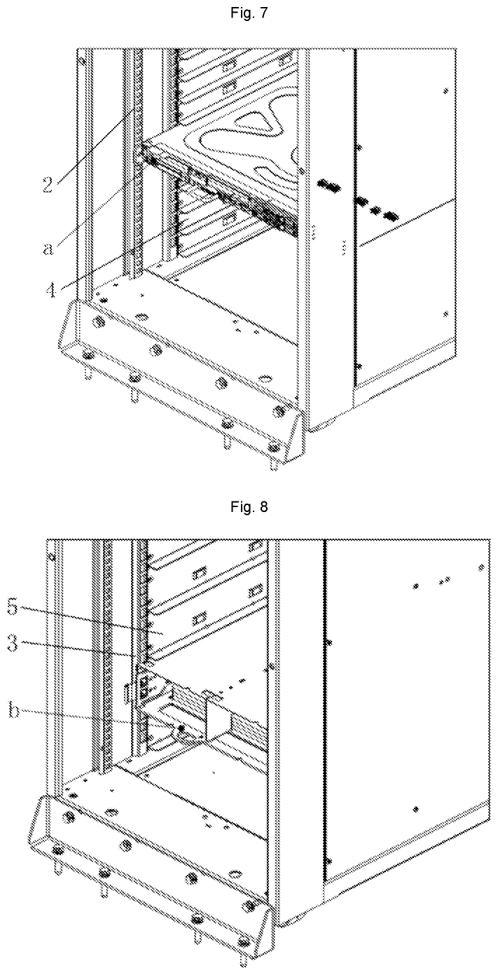

As shown in FIGS. 7 and 8, FIG. 7 is a schematic diagram of a matching structure between an ODCC server a and first mounting flanges 2; and FIG. 8 is a schematic diagram of a matching structure between an OCP server b and second mounting flanges 3.

In an embodiment regarding the first mounting holes 21 and the second mounting holes 31, both the first mounting holes 21 and the second mounting holes 31 are square holes, and in this way, the first mounting holes and the second mounting holes may form snap fit with square columns arranged at the front ends of the ODCC servers a or the OCP servers b. Definitely, the specific shapes of the first mounting holes 21 and the second mounting holes 31 are not fixed, and the remaining shapes such as round holes and polygonal holes may also be used, which need to be Such as determined according to the shape of connecting components provided at the front ends of the servers.

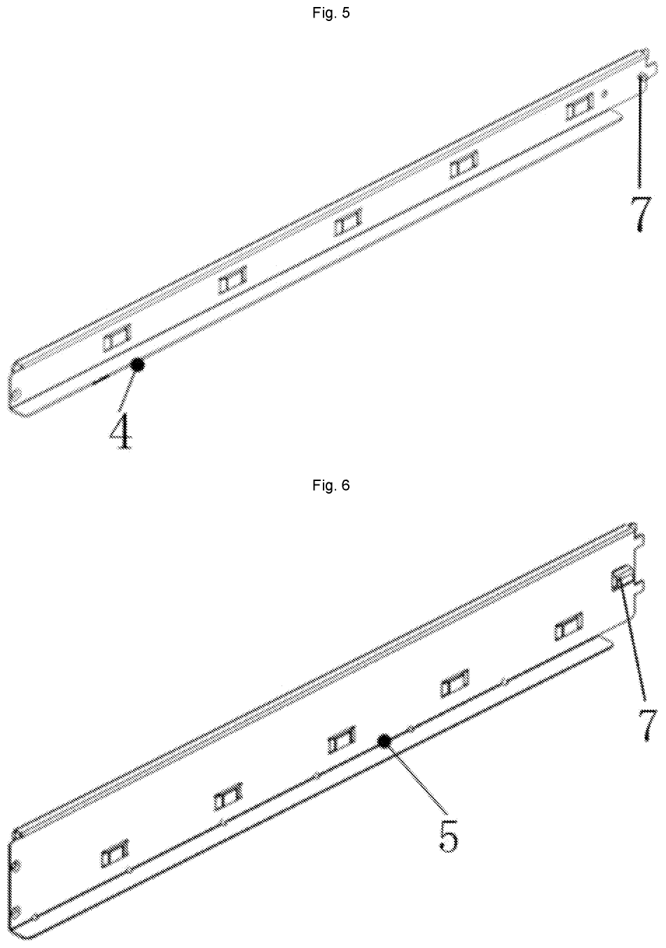

As shown in FIGS. 5 and 6, FIG. 5 is a schematic diagram of the specific structure of a first support bracket 4; and FIG. 6 is a schematic diagram of the specific structure of a second support bracket 5.

In an embodiment regarding the first support brackets 4 and the second support brackets 5, in order to facilitate supporting for the ODCC servers a and the OCP servers b, and ensure that the chassis of the ODCC servers a and the OCP servers b may slide stably in the cabinet frame 1 to realize push-pull plug/unplug, in this embodiment, both the first support brackets 4 and the second support brackets 5 are U-shaped. Such as, each of the first support brackets 4 and the second support brackets 5 includes a groove bottom plate and two side (or bottom single-side) groove wall plates (plate). The groove bottom plate is attached to the inner wall surfaces at the two sides of the cabinet frame 1, and the lengthwise direction of the groove bottom plate is parallel to the mounting direction (depth direction) of the cabinet frame 1, which is generally a horizontal state. The groove wall plates on the two sides are vertically arranged on the surface of the groove bottom plate, and are mainly configured for clamping the bottom surfaces of the chassis of the ODCC servers a and the OCP servers b.

Generally, each inner width of the first support brackets 4 is equivalent to a height of the ODCC server a, and each inner width of the second support brackets 5 is equivalent to a height of the OCP server b, which are equivalent to the width of the groove bottom plate of the first support bracket 4 being equivalent to a height of the ODCC server a, and the width of the groove bottom plate of the second support bracket 5 being equivalent to a height of the OCP server b. In this way, when the ODCC server a is mounted into the first support brackets 4, the groove wall plates on two sides may clamp the surface and the bottom surface of the ODCC server a at the same time, thereby improving the mounting stability of the server a without affecting the sliding thereof. By the same reasoning, when the OCP server b is mounted into the second support brackets 5, the groove wall plates on two side may clamp the surface and the bottom surface of the OCP server b at the same time, thereby improving the mounting stability of the server without affecting the sliding thereof.

Of course, each of the first support brackets 4 and the second support brackets 5 is also provided with one groove wall plate, and at this time, the groove wall plate stands vertically at the bottom of the groove bottom plate to form an L-shaped structure, which is mainly configured for supporting a corresponding server.

In an embodiment, considering that when mounting the server, the server needs to be inserted into the first support brackets 4 or the second support brackets 5 for sliding, and in order to prevent the server from violently hitting the rear cover of the cabinet frame 1 or remaining structures such as busbars in the sliding process, in this embodiment, limiting blocks 7 are provided in the rear end areas of the first support brackets 4 and the second support brackets 5. Such as, the limiting blocks 7 are mainly configured to prevent the ODCC server a or the OCP server b from going forward, thereby preventing the ODCC server a or the OCP server b from being mounted too deep when the server is slidably inserted into the first support brackets 4 or the second support brackets 5, thereby further limiting the maximum installing depth of the ODCC server a and the OCP server b in the cabinet frame 1.

In addition, in order to facilitate centralized power supply of the ODCC server a and the OCP server b, busbars generally need to be integrated and mounted in the cabinet frame 1, wherein the busbars include ODCC busbars c adapted to the ODCC servers a and OCP busbars d adapted to the OCP servers b. In this embodiment, in order to facilitate the assembly and disassembly of the ODCC busbars c and the OCP busbars d, first locking attachment members 8 and second locking attachment members 9 are provided on side walls of the rear end of the cabinet frame 1. The first locking attachment members 8 are mainly configured for locking and attaching the ODCC busbars c onto the side walls of the rear end of the cabinet frame 1 by fasteners such as bolts and rivets, and the second locking attachment members 9 are mainly configured for locking and attaching the OCP busbars d onto the side walls of the rear end of the cabinet frame 1 by fasteners such as bolts and rivets.

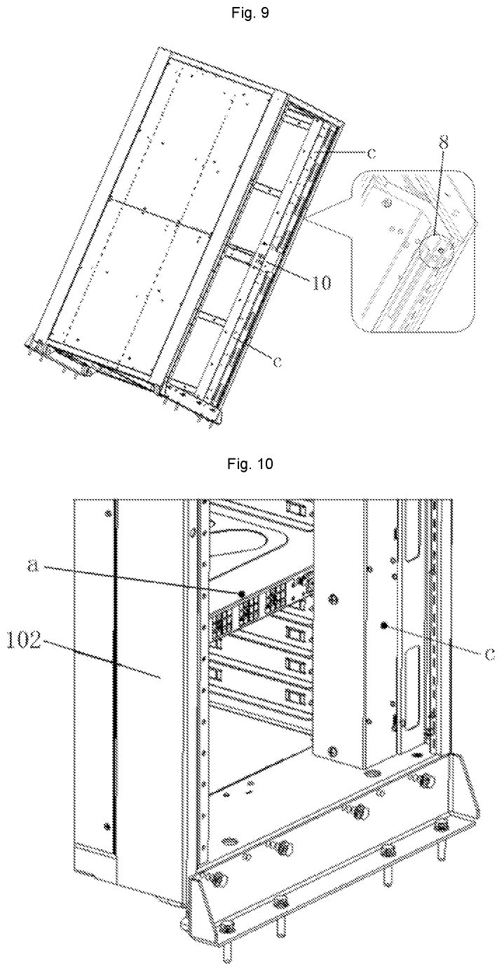

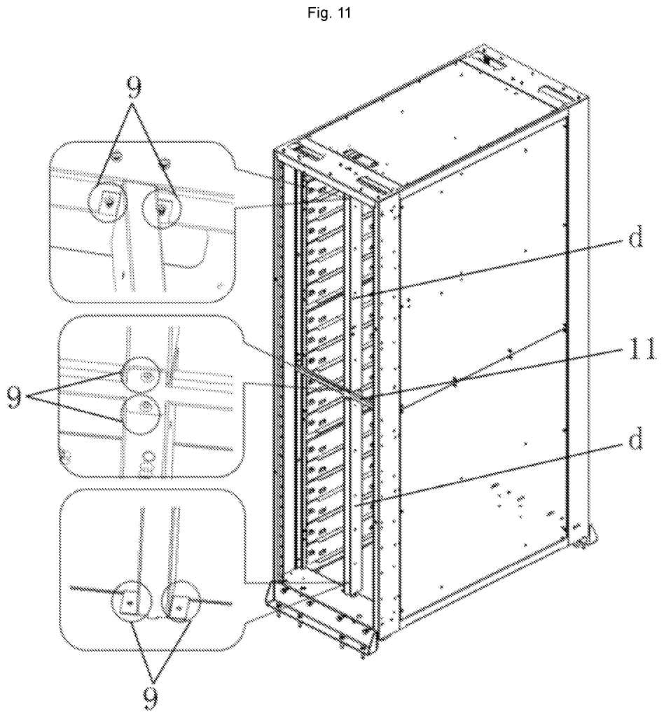

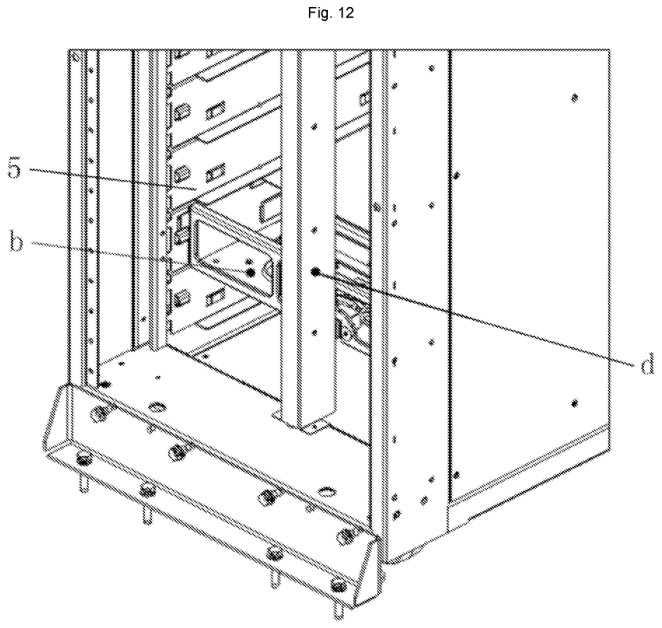

As shown in FIGS. 9, 10, 11 and 12, FIG. 9 is a schematic diagram of a matching structure between ODCC busbars c and first locking attachment members 8; FIG. 10 is a schematic diagram of a partial structure of FIG. 9; FIG. 11 is a schematic diagram of a matching structure between OCP busbars d and second locking attachment members 9; and FIG. 12 is a schematic diagram of a partial structure of FIG. 11.

Generally, in order to avoid mutual interference between the mounting positions of the ODCC busbars c and the OCP busbars d, the ODCC busbars c may be arranged on the (left side or right side) rear vertical post 102 at the rear end of the cabinet frame 1, and then the ODCC busbars c are fixed on the rear vertical post 102 by the first locking attachment members 8. Moreover, the OCP busbars d may be provided at a central position of the rear end of the cabinet frame 1, and are close to the top side wall or the bottom side wall of the cabinet frame 1, and then the OCP busbars d are fixed on the top side wall surface or the bottom side wall surface of the cabinet frame 1 by the second locking attachment members 9.

Further, according to the difference between the arrangement positions and the number of the first support brackets 4 and the second support brackets 5 in the cabinet frame 1, the arrangement situation of the ODCC busbars c and the OCP busbars d at the rear end of the cabinet frame 1 changes accordingly; for example, the first support brackets 4 are all arranged in the upper half area of the cabinet frame 1, and the second support brackets 5 are all arranged in the lower half area of the cabinet frame 1; at this time, one ODCC busbars c is provided and is arranged in the upper half area of the rear vertical post 102, and also one OCP busbars d is provided and is arranged in the central area of the surface of the bottom side wall at the rear end of the cabinet frame 1.

In addition, if only the first support brackets 4 are provided in the cabinet frame 1, two ODCC busbars c are provided at the same time, and are respectively distributed in the upper and lower half areas of the rear vertical post 102. In this case, in order to facilitate docking of the two ODCC busbars c, in this embodiment, a butt block 10 is provided at the middle position in a height direction of the rear vertical post 102, so that the two ODCC busbars c are vertically docked, thereby facilitating unified power supply and management of a power source. By the same reasoning, if only the second support brackets 5 are provided in the cabinet frame 1, two OCP busbars d are provided at the same time, and are distributed at the middle positions of the top side wall and the bottom side wall of the rear end of the cabinet frame 1 at the same time. In this case, in order to facilitate docking of the two OCP busbars d, in this embodiment, a butt cross beam 11 is transversely connected between the two side walls of the rear end of the cabinet frame 1, so that the two OCP busbars are vertically docked, thereby facilitating unified power supply and management of a power source.

The illustrations of the disclosed embodiments enable a person skilled in the art to implement or use some embodiments of the disclosure. Various modifications to these embodiments will be apparent to a person skilled in the art. The general principles defined herein may be implemented in other embodiments without departing from the spirit or scope of the disclosure. Accordingly, the disclosure will not be limited to these embodiments shown herein, but needs to comply with the widest scope consistent with the principles and novel features disclosed herein.

1. A server cabinet, comprising: a cabinet frame, first mounting flanges detachably and vertically arranged at two sides of a front end of the cabinet frame, second mounting flanges detachably and vertically arranged at the two sides of the front end of the cabinet frame, first support brackets detachably arranged at the two side walls of the cabinet frame and configured for installing an ODCC server, and second support brackets detachably arranged at the two side walls of the cabinet frame and configured for installing an OCP server; wherein a plurality of first mounting holes configured for being matched with a front end of the ODCC server are formed in the first mounting flanges along a height direction, and a plurality of second mounting holes configured for being matched with a front end of the OCP server are formed in the second mounting flanges along the height direction.

2. The server cabinet according to claim 1, wherein front vertical posts are provided at the two sides of the front end of the cabinet frame, and the first mounting flanges and the second mounting flanges are both provided on the front vertical posts.

3. The server cabinet according to claim 2, wherein a plurality of columns of mounting holes are provided on surfaces of the front vertical posts along a mounting direction, and the first mounting flanges and the second mounting flanges respectively match corresponding columns of mounting holes of the plurality of columns of mounting holes.

4. The server cabinet according to claim 2, wherein the first mounting flanges and the second mounting flanges are integrally connected by connecting plates, and the connecting plates are detachably provided on the front vertical posts.

5. The server cabinet according to claim 2, wherein the first mounting flanges are closer to the front end of the cabinet frame than the second mounting flanges.

6. The server cabinet according to claim 1, wherein both the first mounting holes and the second mounting holes are square holes, round holes, or polygonal holes.

7. The server cabinet according to claim 1, wherein both the first support brackets and the second support brackets are U-shaped supports, and each inner width of the first support brackets is equivalent to a height of the ODCC server, and each inner width of the second support brackets is equivalent to a height of the OCP server.

8. The server cabinet according to claim 7, wherein rear ends of the first support brackets and the second support brackets are respectively provided with limiting blocks for blocking the ODCC server and the OCP server to limit the maximum installing depth of the ODCC server and the OCP server in the cabinet frame.

9. The server cabinet according to claim 1, wherein the server cabinet further comprises first locking attachment members provided on side walls of a rear end of the cabinet frame and for fixing ODCC busbars, and second locking attachment members provided on side walls of the rear end of the cabinet frame and for fixing OCP busbars.

10. The server cabinet according to claim 9, wherein the server cabinet further comprises a butt block provided at a middle part in the height direction of the side walls of the rear end of the cabinet frame and for vertically abutting joint two of the ODCC busbars; and a butt cross beam transversely connected between the two side walls of the rear end of the cabinet frame and for vertically abutting joint two of the OCP busbars.

11. The server cabinet according to claim 1, wherein the cabinet frame is in a shape of a vertical cuboid, the cabinet frame comprises a bottom plate, a top plate, side covers, a front cover, and a rear cover.

12. The server cabinet according to claim 1, wherein a plurality of first support brackets are stacked in the height direction of the cabinet frame.

13. The server cabinet according to claim 1, wherein a plurality of second support brackets are stacked in the height direction of the cabinet frame.

14. The server cabinet according to claim 2, wherein the front vertical posts at the two sides are connected to form a rectangular enclosure frame, and are sleeved on the front end of the cabinet frame.

15. The server cabinet according to claim 3, wherein the first mounting flanges stand on an outer end edge positions of the front vertical posts, and the second mounting flanges stand on an inner end edge positions of the front vertical posts.

16. The server cabinet according to claim 7, wherein each of the first support brackets and the second support brackets comprises a groove bottom plate and two side groove wall plates, the groove bottom plate is attached to an inner wall surfaces at the two sides of the cabinet frame, and a lengthwise direction of the groove bottom plate is parallel to a depth direction of the cabinet frame.

17. The server cabinet according to claim 7, wherein each of the first support brackets and the second support brackets is provided with one groove wall plate and a groove bottom plate, the groove wall plate stands vertically at a bottom of the groove bottom plate to form an L-shaped structure.

18. The server cabinet according to claim 9, wherein
the first locking attachment members comprise bolts or rivets; or
the second locking attachment members comprise bolts or rivets.

19. The server cabinet according to claim 9, wherein the OCP busbars are provided at a central position of the rear end of the cabinet frame.

20. The server cabinet according to claim 9, wherein the first support brackets are arranged in an upper half area of the cabinet frame, and the second support brackets are arranged in a lower half area of the cabinet frame.
